(19) United States
(12) Patent Application Publication
(10) Pub. No.: US 2018/0302047 A1
(43) Pub. Date: Oct. 18, 2018

(54) POWER AMPLIFIER MODULE AND RADIO FREQUENCY MODULE

(71) Applicant: Murata Manufacturing Co., Ltd., Kyoto (JP)

(72) Inventors: Hirotake IGARASHI, Kyoto (JP); Takayuki SHINOZAKI, Kyoto (JP); Satoshi TANAKA, Kyoto (JP)

(21) Appl. No.: 15/950,934

(22) Filed: Apr. 11, 2018

(30) Foreign Application Priority Data
Apr. 12, 2017 (JP) 2017-078906
Jan. 24, 2018 (JP) 2018-009580

(51) Int. Cl. H03F 3/217

(52) U.S. Cl. CPC H03F 3/217; H03F 3/195

(57) ABSTRACT

A power amplifier module includes a plurality of power amplifiers and at least one switch that switches between power supply sources such that each of the plurality of power amplifiers is supplied with one of a power supply voltage according to an envelope tracking scheme or a power supply voltage according to an average power tracking scheme.

This application claims priority from Japanese Patent Application No. JP2017-078906 filed on Apr. 12, 2017 which claims priority from Japanese Patent Application No. JP2018-009580 filed on Jan. 24, 2018. The content of these applications are incorporated herein by reference in their entireties

### BACKGROUND

The present disclosure relates to a power amplifier module and a radio frequency module. Recent mobile communication terminals such as cellular phones adopt modulation schemes for high-speed data communication standards, such as High Speed Uplink Packet Access (HSUPA), Long Term Evolution (LTE), or LTE-Advanced. Such communication standards require high-linearity power amplifier modules to amplify radio frequency (RF) signals. In such communication standards, the range over which an RF signal changes in amplitude (dynamic range) is typically increased to improve the communication speed. In a large dynamic range, a high power supply voltage is also required to increase linearity, which tends to result in greater power consumption of a power amplifier module. In the backdrop of such a situation, a power amplifier module is proposed in U.S. Patent Application Publication No. 2014/0111178 that is capable of switching the operating mode of an amplifier to any one of an envelope tracking mode, an average power tracking mode, and a transition mode. Known examples of technology for improved communication speeds of mobile communication terminals include carrier aggregation in which a plurality of component carriers of different frequency ranges are aggregated such that RF signals are simultaneously transmitted and received over a single communication line.

However, the power amplifier module described in U.S. Patent Application Publication No. 2014/0111178 does not support carrier aggregation. Thus, in order to aggregate a plurality of component carriers and perform an uplink carrier aggregation operation, an envelope tracking power supply circuit for supplying a power supply voltage is required for each amplifier configured to amplify a component carrier. For example, in order to aggregate three component carriers and perform an uplink carrier aggregation operation, three envelope tracking power supply circuits are required, which inevitably leads to an increase in the circuit size and cost of the power amplifier module.

### BRIEF SUMMARY

Accordingly, the present disclosure provides a power amplifier module with reduced circuit size and cost.

According to embodiments of the present disclosure, a power amplifier module includes a plurality of power amplifiers and at least one switch that switches between power supply sources such that each of the plurality of power amplifiers is supplied with one of a power supply voltage according to an envelope tracking scheme or a power supply voltage according to an average power tracking scheme.

According to embodiments of the present disclosure, the circuit size and cost of a power amplifier module can be reduced.

Other features, elements, characteristics and advantages of the present disclosure will become more apparent from the following detailed description of embodiments of the present disclosure with reference to the attached drawings.

### BRIEF DESCRIPTION OF THE SEVERAL VIEWS OF THE DRAWINGS

FIG. 1 illustrates a circuit configuration of a radio frequency module according to a first embodiment of the present disclosure;

FIG. 2 illustrates a circuit configuration of a radio frequency module according to a second embodiment of the present disclosure;

FIG. 3 illustrates a circuit configuration of a radio frequency module according to a third embodiment of the present disclosure;

FIG. 4 illustrates a circuit configuration of a radio frequency module according to a modification of the first embodiment of the present disclosure;

FIG. 5 illustrates a circuit configuration of a radio frequency module according to another modification of the first embodiment of the present disclosure;

FIG. 6 illustrates module substrates having components of the radio frequency module according to the first embodiment of the present disclosure;

FIG. 7 illustrates a circuit configuration of a radio frequency module according to a fourth embodiment of the present disclosure; and

FIG. 8 is a flowchart illustrating a method for determining a power supply voltage when a carrier aggregation operation is performed in the first embodiment of the present disclosure.

### DETAILED DESCRIPTION

Embodiments of the present disclosure will be described hereinafter with reference to the drawings. In the drawings, circuit elements denoted by the same numeral represent and the same or substantially the same circuit elements are not repeatedly described.

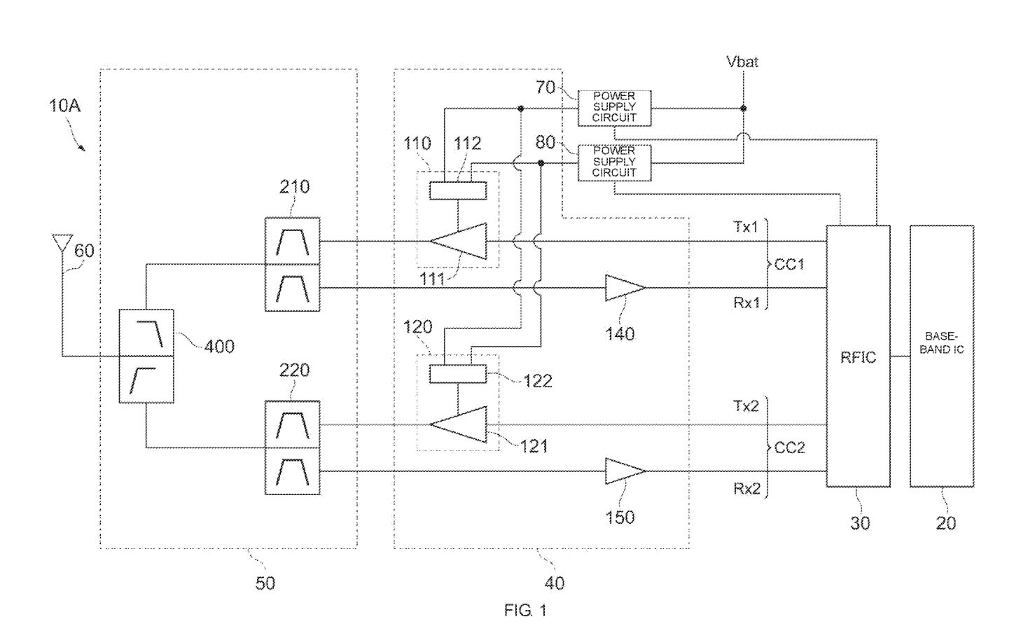

FIG. 1 illustrates a circuit configuration of a radio frequency module 10A according to a first embodiment of the present disclosure. The radio frequency module 10A is a module included in a mobile communication terminal such as a cellular phone and configured to perform a process for transmitting and receiving a plurality of RF signals having different frequency ranges to and from a base station. The radio frequency module 10A is also referred to as a transceiver module.

The radio frequency module 10A is configured to be capable of performing a carrier aggregation operation using two component carriers CC1 and CC2 of different frequency ranges. Herein, an RF signal on an uplink channel in the component carrier CC1 is referred to as a transmit signal Tx1 and an RF signal on a downlink channel in the component carrier CC1 is referred to as a receive signal Rx1. Further, an RF signal on an uplink channel in the component carrier CC2 is referred to as a transmit signal Tx2 and an RF signal on a downlink channel in the component carrier CC2 is referred to as a receive signal Rx2. The two component carriers CC1 and CC2 may be in a combination of different frequency ranges based on the same communication standard or may be based on a combination of different communication standards such as a combination of LTE and the fifth generation mobile communication system (5G), a combination of Wi-Fi and BLUETOOTH®, or a combination of LTE and License-Assisted Access using LTE (LAA-LTE). Table 1 below gives exemplary combinations of two frequency ranges for LTE in which the two component carriers CC1 and CC2 may be placed. Table 2 below gives exemplary combinations of communication standards on which the two component carriers CC1 and CC2 may be based.

TABLE 1

| CC1 | CC2 |
|---|---|
| Band 1 | Band 3 |
| Band 1 | Band 5 |
| Band 1 | Band 8 |
| Band 1 | Band 11 |
| Band 1 | Band 18 |
| Band 1 | Band 19 |
| Band 1 | Band 20 |
| Band 1 | Band 21 |
| Band 1 | Band 26 |
| Band 1 | Band 28 |
| Band 1 | Band 40 |
| Band 1 | Band 41 |
| Band 1 | Band 42 |
| Band 2 | Band 5 |
| Band 2 | Band 13 |
| Band 3 | Band 5 |
| Band 3 | Band 7 |
| Band 3 | Band 8 |
| Band 3 | Band 19 |
| Band 3 | Band 20 |
| Band 3 | Band 26 |
| Band 3 | Band 28 |
| Band 3 | Band 41 |
| Band 3 | Band 42 |
| Band 3 | Band 46 |
| Band 4 | Band 5 |
| Band 4 | Band 7 |
| Band 4 | Band 12 |
| Band 4 | Band 13 |
| Band 4 | Band 17 |
| Band 4 | Band 46 |
| Band 5 | Band 7 |
| Band 5 | Band 17 |
| Band 5 | Band 30 |
| Band 5 | Band 40 |
| Band 5 | Band 66 |
| Band 7 | Band 8 |
| Band 7 | Band 20 |
| Band 7 | Band 28 |
| Band 8 | Band 39 |
| Band 12 | Band 30 |
| Band 12 | Band 66 |
| Band 13 | Band 66 |
| Band 19 | Band 42 |
| Band 28 | Band 42 |

TABLE 2

| CC1 | CC2 |
|---|---|
| LTE | 5G New Radio |
| LTE | Bluetooth |
| LTE | Wi-Fi |
| 5G New Radio | Wi-Fi |
| 5G New Radio | Bluetooth |
| Wi-Fi | Bluetooth |
| LTE | E-LAA (LAA) |
| E-LAA (LAA) | 5G New Radio |

The radio frequency module 10A includes a baseband integrated circuit (IC) 20, a radio frequency integrated circuit (RFIC) 30, a power amplifier module 40, a front-end module 50, and power supply circuits 70 and 80.

The baseband IC 20 modulates an input signal such as an audio signal or a data signal in accordance with a predetermined modulation scheme and outputs the modulated signal. Further, the baseband IC 20 demodulates the modulated signal in accordance with a predetermined modulation scheme. The modulated signal has a frequency of about several megahertz (MHz) to several hundreds of megahertz (MHz), for example. The RFIC 30 generates the transmit signals Tx1 and Tx2, which are to be wirelessly transmitted, from the modulated signal output from the baseband IC 20. Each transmit signal has a frequency of about several hundreds of megahertz (MHz) to several tens of gigahertz (GHz), for example, and has a different band width depending on the communication standard or the frequency range. Further, the RFIC 30 demodulates the receive signals Rx1 and Rx2, which are output from the power amplifier module 40, into modulated signals. Further, the RFIC 30 controls the power supply circuits 70 and 80 to provide a power supply voltage to the power amplifier module 40. The power supply circuits 70 and 80 may be controlled by the baseband IC 20 instead of by the RFIC 30.

The power amplifier module 40 includes a power amplifier circuit 110 that amplifies the power of the transmit signal Tx1, a power amplifier circuit 120 that amplifies the power of the transmit signal Tx2, a low-noise amplifier 140 that amplifies the power of the receive signal Rx1, and a low-noise amplifier 150 that amplifies the power of the receive signal Rx2. The front-end module 50 includes duplexers 210 and 220 and a diplexer 400. The duplexer 210 separates the transmit signal Tx1 and the receive signal Rx1 in the component carrier CC1. The duplexer 220 separates the transmit signal Tx2 and the receive signal Rx2 in the component carrier CC2. The diplexer 400 separates the component carriers CC1 and CC2.

The transmit signal Tx1 whose power is amplified by the power amplifier circuit 110 passes through the duplexer 210 and the diplexer 400 and is transmitted from an antenna 60. The receive signal Rx1, which is received by the antenna 60, passes through the diplexer 400 and the duplexer 210 and is input to the RFIC 30 via the low-noise amplifier 140. The transmit signal Tx2 whose power is amplified by the power amplifier circuit 120 passes through the duplexer 220 and the diplexer 400 and is transmitted from the antenna 60. The receive signal Rx2, which is received by the antenna 60, passes through the diplexer 400 and the duplexer 220 and is input to the RFIC 30 via the low-noise amplifier 150.

The power supply circuit 70 is a power supply source that supplies a power supply voltage to the power amplifier circuits 110 and 120 according to an envelope tracking scheme. In the envelope tracking scheme, a power supply voltage to be supplied to the power amplifier circuits 110 and 120 is controlled in accordance with the amplitude level of an RF signal input to the power amplifier circuits 110 and 120. The power supply circuit 70 is an envelope tracking power supply circuit that steps up or down a battery voltage Vbat on the basis of, for example, a control signal provided by the RFIC 30 and that supplies the resulting battery voltage Vbat to the power amplifier circuits 110 and 120. The battery voltage Vbat is a supply voltage provided from a battery such as a lithium ion battery mounted in a mobile communication terminal, for example. The power supply circuit 80 is a power supply source that supplies a power supply voltage to the power amplifier circuits 110 and 120 according to an average power tracking scheme. In the average power tracking scheme, a power supply voltage to be supplied to the power amplifier circuits 110 and 120 is controlled in accordance with average output power. The power supply circuit 80 is a DC/DC converter (an average power tracking power supply circuit) that steps up or down the battery voltage Vbat in accordance with average output power on the basis of, for example, a control signal provided by the RFIC 30 and that supplies the resulting battery voltage Vbat to the power amplifier circuits 110 and 120. The power amplifier circuit 110 includes an amplifier 111 that amplifies the power of the transmit signal Tx1, and a switch 112 that switches between power supply sources such that power is supplied from any one selected from among the power supply circuits 70 and 80. The amplifier 111 is supplied with power from either power supply source via the switch 112. The power amplifier circuit 120 includes an amplifier 121 that amplifies the power of the transmit signal Tx2, and a switch 122 that switches between power supply sources such that power is supplied from any one selected from among the power supply circuits 70 and 80. The amplifier 121 is supplied with power from either power supply source via the switch 122. Each of the amplifiers 111 and 121 includes a transistor element such as a heterojunction bipolar transistor. Transistor elements that are multistage interconnected may be used. The switches 112 and 122 each include a semiconductor switch such as a field-effect transistor, and the on state and the off state of the semiconductor switch are switched to selectively switch between power supply sources. The switching of power supply sources using each of the switches 112 and 122 is controlled by, for example, the baseband IC 20 or the RFIC 30 although control lines are not illustrated in FIG. 1.

The power amplifier circuits 110 and 120 can simultaneously output a plurality of RF signals having different frequency ranges by using carrier aggregation. In this case, any one power amplifier circuit selected from among the two power amplifier circuits 110 and 120 is supplied with a power supply voltage from the power supply circuit 70 according to the envelope tracking scheme, and the power amplifier circuit other than the selected power amplifier circuit is supplied with a power supply voltage from the power supply circuit 80 according to the average power tracking scheme. For example, when the power amplifier circuit 110 is selected as a power amplifier circuit supplied with power from the power supply circuit 70, the switch 112 switches between power supply sources so that the power supply circuit 70 serves as a power supply source that provides power to the power amplifier circuit 110. In this case, the switch 122 switches between power supply sources so that the power supply circuit 80 serves as a power supply source that provides power to the power amplifier circuit 120. For example, when the power amplifier circuit 120 is selected as a power amplifier circuit supplied with power from the power supply circuit 70, the switch 122 switches between power supply sources so that the power supply circuit 70 serves as a power supply source that provides power to the power amplifier circuit 120. In this case, the switch 112 switches between power supply sources so that the power supply circuit 80 serves as a power supply source that provides power to the power amplifier circuit 110.

In this way, one of the power amplifier circuits 110 and 120 that perform a carrier aggregation operation is supplied with a power supply voltage according to the envelope tracking scheme from the power supply circuit 70, and the other power amplifier circuit is supplied with a power supply voltage according to the average power tracking scheme from the power supply circuit 80. This circuit configuration eliminates the need to provide two envelope tracking power supply circuits to supply a power supply voltage to the power amplifier circuits 110 and 120 that perform a carrier aggregation operation. A single envelope tracking power supply circuit and a single average power tracking power supply circuit, instead of two envelope tracking power supply circuits, are provided, which can reduce the circuit size and cost of the power amplifier module 40.

In the envelope tracking scheme, a power supply voltage is controlled so as to allow the power amplifier circuits 110 and 120 to operate in a high-efficiency state at or around saturation power levels relative to an input power level. Thus, high efficiency is achieved across a wide input power range. As a result, the interfering wave output from a power amplifier circuit supplied with a power supply voltage according to the envelope tracking scheme is large, which is undesirable. It is therefore desirable that, during a carrier aggregation operation, the output power of a power amplifier circuit supplied with a power supply voltage according to the envelope tracking scheme be reduced and the reduced power be compensated for by a power amplifier circuit supplied with a power supply voltage according to the average power tracking scheme. Accordingly, the influence of the interfering wave can be reduced. In addition, to compensate for the reduced output power of a power amplifier circuit supplied with a power supply voltage according to the envelope tracking scheme, a power amplifier circuit supplied with a power supply voltage according to the average power tracking scheme is caused to operate with high efficiency, which enables the output power of the antenna 60 to be adjusted to a specified output level. As an example, to achieve the antenna 60 with an output power of, for example, 24 dBm, the output power of a power amplifier circuit supplied with a power supply voltage according to the envelope tracking scheme may be set to 23 dBm, for example, and the output power of a power amplifier circuit supplied with a power supply voltage according to the average power tracking scheme may be set to 17 dBm, for example. The power supply circuit 70 is not limited to an envelope tracking power supply circuit and may be, for example, a power supply circuit capable of supplying a power supply voltage regardless of whether the envelope tracking scheme or the average power tracking scheme is used.

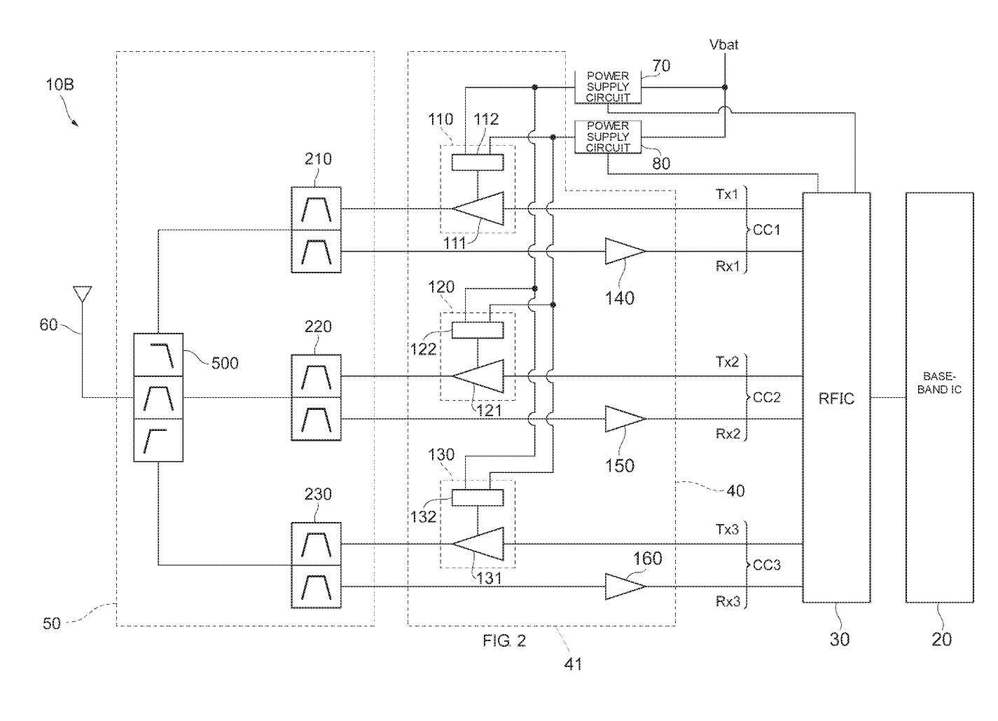

FIG. 2 illustrates a circuit configuration of a radio frequency module 10B according to a second embodiment of the present disclosure. The radio frequency module 10B is configured to be capable of performing a carrier aggregation operation using three component carriers CC1, CC2, and CC3 of different frequency ranges. Herein, an RF signal on an uplink channel in the component carrier CC3 is referred to as a transmit signal Tx3 and an RF signal on a downlink channel in the component carrier CC3 is referred to as a receive signal Rx3. Unlike the power amplifier module 40 of the radio frequency module 10A, a power amplifier module 41 of the radio frequency module 10B further includes a power amplifier circuit 130 in addition to the power amplifier circuits 110 and 120, and a low-noise amplifier 160 in addition to the low-noise amplifiers 140 and 150. Unlike the front-end module 50 of the radio frequency module 10A, a front-end module 50 of the radio frequency module 10B further includes a duplexer 230 in addition to the duplexers 210 and 220. Unlike the front-end module 50 of the radio frequency module 10A, the front-end module 50 of the radio frequency module 10B includes a triplexer 500 instead of the diplexer 400.

The duplexer 230 separates the transmit signal Tx3 and the receive signal Rx3 in the component carrier CC3. The triplexer 500 separates the component carriers CC1, CC2, and CC3. The transmit signal Tx1 whose power is amplified by the power amplifier circuit 110 passes through the duplexer 210 and the triplexer 500 and is transmitted from the antenna 60. The receive signal Rx1, which is received by the antenna 60, passes through the triplexer 500 and the duplexer 210 and is input to the RFIC 30 through the low-noise amplifier 140. The transmit signal Tx2 whose power is amplified by the power amplifier circuit 120 passes through the duplexer 220 and the triplexer 500 and is transmitted from the antenna 60. The receive signal Rx2, which is received by the antenna 60, passes through the triplexer 500 and the duplexer 220 and is input to the RFIC 30 through the low-noise amplifier 150. The transmit signal Tx3 whose power is amplified by the power amplifier circuit 130 passes through the duplexer 230 and the triplexer 500 and is transmitted from the antenna 60. The receive signal Rx3, which is received by the antenna 60, passes through the triplexer 500 and the duplexer 230 and is input to the RFIC 30 through the low-noise amplifier 160.

The power amplifier circuit 130 includes an amplifier 131 that amplifies the power of the transmit signal Tx3, and a switch 132 that switches between power supply sources such that power is supplied from any one selected from among the power supply circuits 70 and 80. The amplifier 131 is supplied with power from either power supply source via the switch 132. The amplifier 131 includes a transistor element such as a heterojunction bipolar transistor. Transistor elements that are multistage interconnected may be used. The switch 132 includes a semiconductor switch such as a field-effect transistor, and the on state and the off state of the semiconductor switch are switched to selectively switch between power supply sources. The switching of power supply sources using the switch 132 is controlled by, for example, the baseband IC 20 or the RFIC 30. The power amplifier circuits 110, 120, and 130 can simultaneously output a plurality of RF signals having different frequency ranges by using carrier aggregation. In this case, any one power amplifier circuit selected from among the three power amplifier circuits 110, 120, and 130 is supplied with a power supply voltage from the power supply circuit 70 according to the envelope tracking scheme, and the power amplifier circuits other than the selected power amplifier circuit are supplied with the same power supply voltage from the power supply circuit 80 according to the average power tracking scheme. For example, when the power amplifier circuit 110 is selected as a power amplifier circuit supplied with power from the power supply circuit 70, the switch 112 switches between power supply sources so that the power supply circuit 70 serves as a power supply source that provides power to the power amplifier circuit 110. In this case, the switch 122 switches between power supply sources so that the power supply circuit 80 serves as a power supply source that provides power to the power amplifier circuit 120. Also, the switch 132 switches between power supply sources so that the power supply circuit 80 serves as a power supply source that provides power to the power amplifier circuit 130. The power supply circuit 80 supplies the same power supply voltage to the power amplifier circuits 120 and 130. The power supply circuit 80 may supply a power supply voltage in accordance with the average power of, for example, one of the power amplifier circuits 120 and 130 having higher output power. For example, when the power amplifier circuit 120 is selected as a power amplifier circuit supplied with power from the power supply circuit 70, the switch 122 switches between power supply sources so that the power supply circuit 70 serves as a power supply source that provides power to the power amplifier circuit 120. In this case, the switch 112 switches between power supply sources so that the power supply circuit 80 serves as a power supply source that provides power to the power amplifier circuit 110. Also, the switch 132 switches between power supply sources so that the power supply circuit 80 serves as a power supply source that provides power to the power amplifier circuit 130. The power supply circuit 80 supplies the same power supply voltage to the power amplifier circuits 110 and 130. The power supply circuit 80 may supply a power supply voltage in accordance with the average power of, for example, one of the power amplifier circuits 110 and 130 having higher output power. For example, when the power amplifier circuit 130 is selected as a power amplifier circuit supplied with power from the power supply circuit 70, the switch 132 switches between power supply sources so that the power supply circuit 70 serves as a power supply source that provides power to the power amplifier circuit 130. In this case, the switch 112 switches between power supply sources so that the power supply circuit 80 serves as a power supply source that provides power to the power amplifier circuit 110. Also, the switch 122 switches between power supply sources so that the power supply circuit 80 serves as a power supply source that provides power to the power amplifier circuit 120. The power supply circuit 80 supplies the same power supply voltage to the power amplifier circuits 110 and 120. The power supply circuit 80 may supply a power supply voltage in accordance with the average power of, for example, one of the power amplifier circuits 110 and 120 having higher output power. In this way, one of the power amplifier circuits 110, 120, and 130 that perform a carrier aggregation operation is supplied with a power supply voltage according to the envelope tracking scheme from the power supply circuit 70, and the other power amplifier circuits are supplied with a power supply voltage according to the average power tracking scheme from the power supply circuit 80. This circuit configuration eliminates the need to provide three envelope tracking power supply circuits to supply a power supply voltage to the power amplifier circuits 110, 120, and 130 that perform a carrier aggregation operation. A single envelope tracking power supply circuit and a single average power tracking power supply circuit, instead of three envelope tracking power supply circuits, are provided, which can reduce the circuit size and cost of the power amplifier module 40.

The number of power supply circuit 80 is not limited to one and may be equal to, for example, the number of power amplifier circuits supplied with a power supply voltage according to the average power tracking scheme. This can further enhance efficiency.

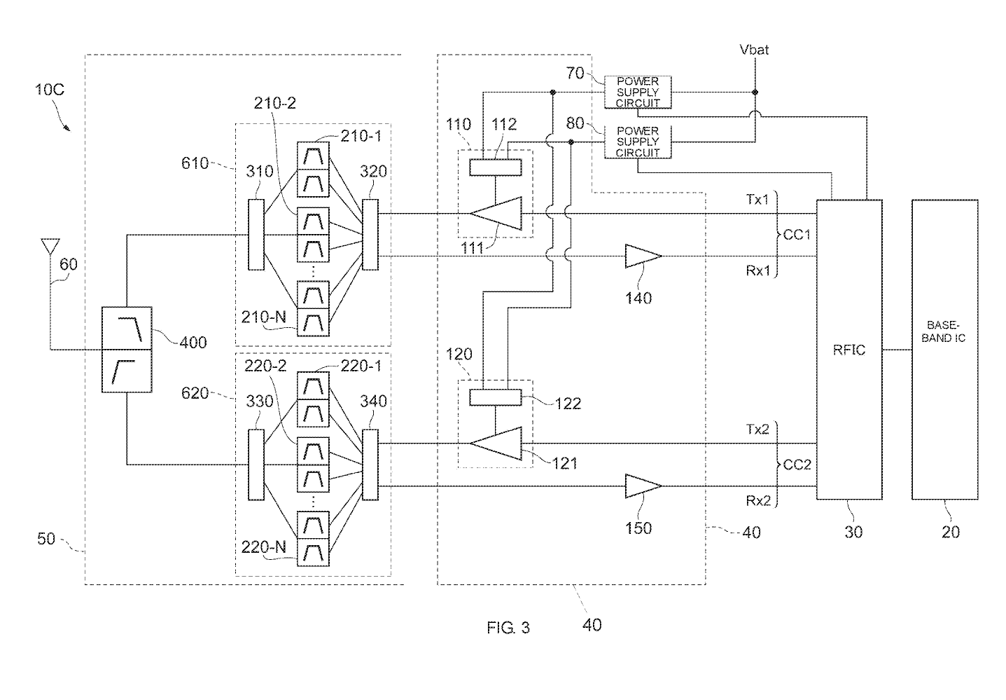

FIG. 3 illustrates a circuit configuration of a radio frequency module 10C according to a third embodiment of the present disclosure. Unlike the front-end module 50 of the radio frequency module 10A, a front-end module 50 of the radio frequency module 10C includes a plurality of filter circuits 610 and 620. Differences between the first and third embodiments are mainly described, whereas common features are not described in detail.

The filter circuit 610 filters an RF signal in the component carrier CC1 (the transmit signal Tx1 and the receive signal Rx1). The filter circuit 610 includes a plurality of duplexers 210-1, 210-2, . . . , and 210-N and a pair of RF switches 310 and 320. One of the pair of RF switches 310 and 320 is disposed on a side of the filter circuit 610 on which the RF signal is input to the plurality of duplexers 210-1, 210-2, . . . , and 210-N, and the other RF switch is disposed on a side of the filter circuit 610 on which the RF signal is output from the plurality of duplexers 210-1, 210-2, . . . , and 210-N. The frequency range of the RF signal in the component carrier CC1 can be changed by selecting from N frequency ranges. The pair of RF switches 310 and 320 selects a duplexer corresponding to a selected frequency range of the RF signal in the component carrier CC1 from among the plurality of duplexers 210-1, 210-2, . . . , and 210-N and selectively switches between paths of the RF signal such that the RF signal is transmitted through the selected duplexer.

Thus, the transmit signal Tx1 whose power is amplified by the power amplifier circuit 110 passes through the RF switch 320, a duplexer selected from among the plurality of duplexers 210-1, 210-2, . . . , and 210-N, the RF switch 310, and the diplexer 400 and is transmitted from the antenna 60. The receive signal Rx1, which is received from the antenna 60, passes through the diplexer 400, the RF switch 310, a duplexer selected from among the plurality of duplexers 210-1, 210-2, . . . , and 210-N, and the RF switch 320 and is input to the RFIC 30 via the low-noise amplifier 140. Here, N is an integer greater than or equal to 2. The filter circuit 620 filters an RF signal in the component carrier CC2 (the transmit signal Tx2 and the receive signal Rx2). The filter circuit 620 includes a plurality of duplexers 220-1, 220-2, . . . , and 220-N and a pair of RF switches 330 and 340. One of the pair of RF switches 330 and 340 is disposed on a side of the filter circuit 620 on which the RF signal is input to the plurality of duplexers 220-1, 220-2, . . . , and 220-N, and the other RF switch is disposed on a side of the filter circuit 620 on which the RF signal is output from the plurality of duplexers 220-1, 220-2, . . . , and 220-N. The frequency range of the RF signal in the component carrier CC2 can be changed by selecting from N frequency ranges. The pair of RF switches 330 and 340 selects a duplexer corresponding to a selected frequency range of the RF signal in the component carrier CC2 from among the plurality of duplexers 220-1, 220-2, . . . , and 220-N and selectively switches between paths of the RF signal such that the RF signal is transmitted through the selected duplexer. Thus, the transmit signal Tx2 whose power is amplified by the power amplifier circuit 120 passes through the RF switch 340, a duplexer selected from among the plurality of duplexers 220-1, 220-2, . . . , and 220-N, the RF switch 330, and the diplexer 400 and is transmitted from the antenna 60. The receive signal Rx2, which is received from the antenna 60, passes through the diplexer 400, the RF switch 330, a duplexer selected from among the plurality of duplexers 220-1, 220-2, . . . , and 220-N, and the RF switch 340 and is input to the RFIC 30 via the low-noise amplifier 150.

The power amplifier circuits 110 and 120 can simultaneously output a plurality of RF signals having different frequency ranges by using carrier aggregation. In addition, since the frequency range of an RF signal in each of the component carriers CC1 and CC2 can be changed, carrier aggregation can be performed for a plurality of frequency ranges.

For convenience of illustration, the third embodiment exemplifies the use of two power amplifier circuits. However, three or more power amplifier circuits may be used. In this case, the number of filter circuits is equal to the number of power amplifier circuits. Each filter circuit includes a plurality of duplexers and a pair of RF switches. The pair of RF switches select, from among the plurality of duplexers, a duplexer corresponding to the frequency range of an RF signal output from one of a plurality of power amplifier circuits and selectively switch between paths of the RF signal such that RF signal is transmitted through the selected duplexer.

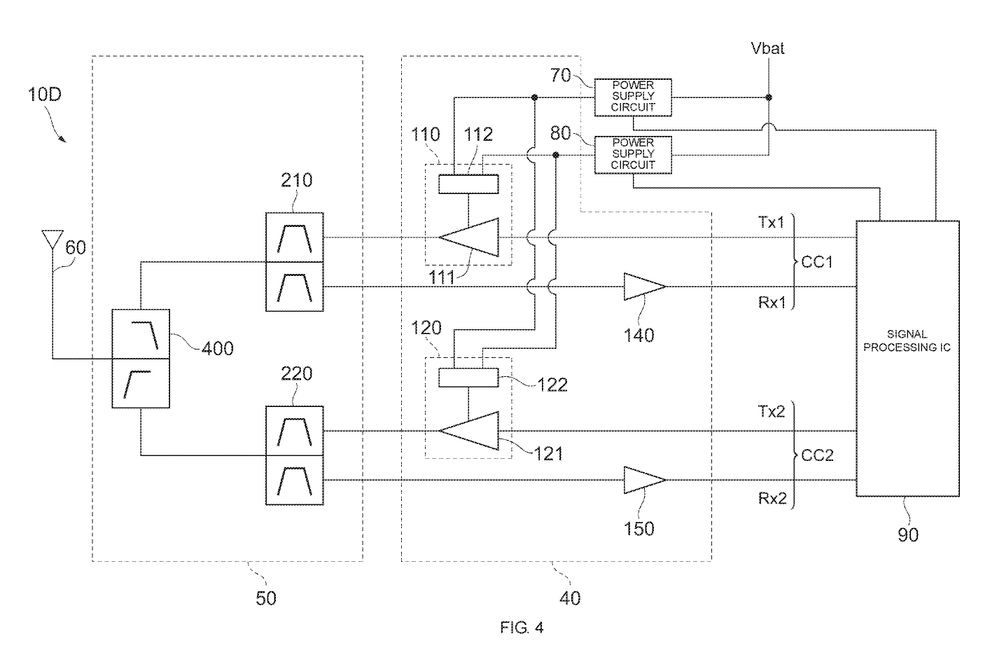

FIG. 4 illustrates a circuit configuration of a radio frequency module 10D according to a modification of the first embodiment of the present disclosure. Unlike the radio frequency module 10A, the radio frequency module 10D includes a signal processing IC 90 instead of the baseband IC 20 and the RFIC 30. That is, in the radio frequency module 10A, the baseband IC 20 and the RFIC 30 are formed as separate chips, whereas in the radio frequency module 10D, these functions are implemented as a single chip.

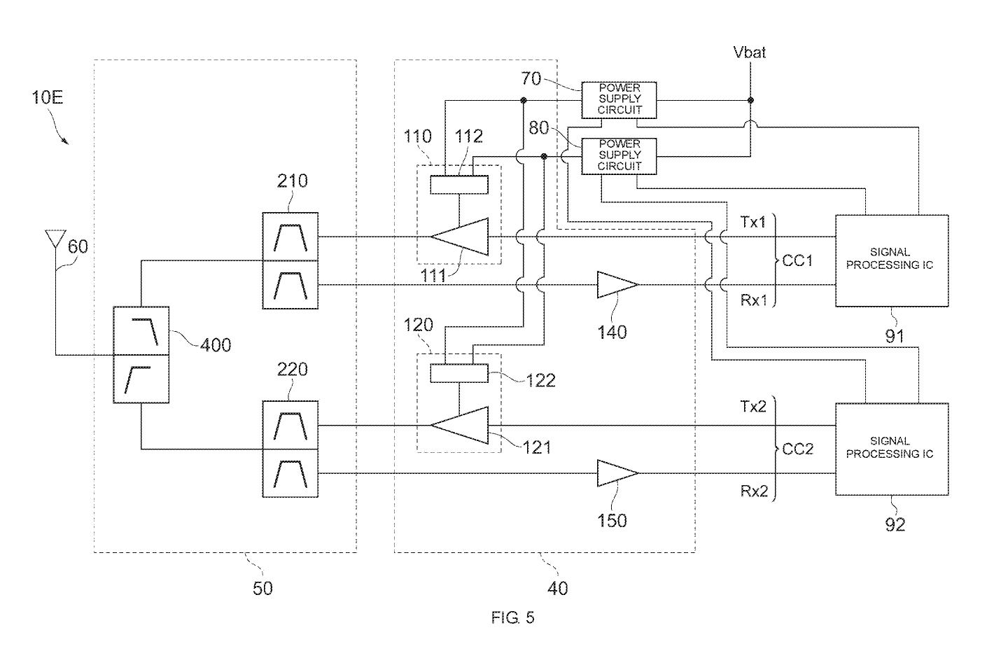

FIG. 5 illustrates a circuit configuration of a radio frequency module 10E according to another modification of the first embodiment of the present disclosure. Unlike the radio frequency module 10D, the radio frequency module 10E includes signal processing ICs 91 and 92 instead of the signal processing IC 90. That is, in the radio frequency module 10D, a signal processing IC is implemented as a single chip, whereas in the radio frequency module 10E, respective signal processing ICs for the component carriers CC1 and CC2 are implemented as separate chips. Thus, for example, when the component carriers CC1 and CC2 are based on different communication standards, the signal processing ICs 91 and 92 can have configurations suitable for the respective communication standards.

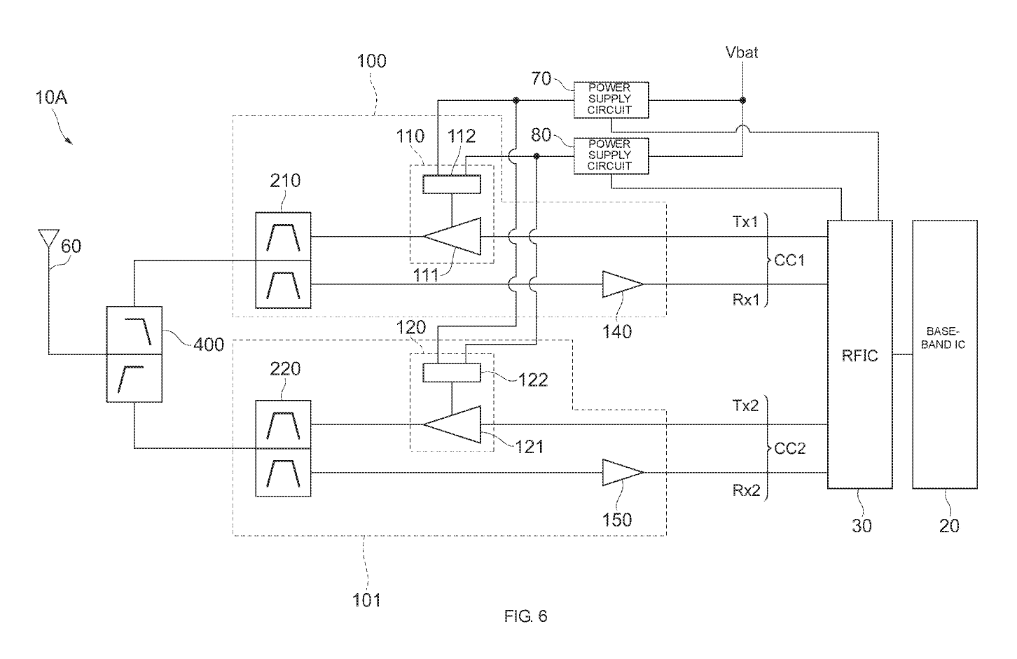

In the radio frequency modules 10A to 10E illustrated in FIGS. 1 to 5, the power supply circuits 70 and 80 are not included in the power amplifier module 40, by way of example. As an alternative to these configurations, the power supply circuits 70 and 80 may be included in the power amplifier module 40. FIG. 6 illustrates module substrates having the components of the radio frequency module 10A according to the first embodiment of the present disclosure. Specifically, in the illustration of FIG. 6, the power amplifier circuit 110, the low-noise amplifier 140, and the duplexer 210 are mounted on a module substrate 100, and the power amplifier circuit 120, the low-noise amplifier 150, and the duplexer 220 are mounted on a module substrate 101. The configuration of the module substrates 100 and 101 illustrated in FIG. 6 is an example, and each of the components of the radio frequency module 10A may be mounted on either of the module substrates 100 and 101. For example, when the module substrate 100 is taken as an example, the low-noise amplifier 140 or the duplexer 210 may be mounted on a different substrate from the module substrate 100. Alternatively, the power amplifier circuits 110 and 120, the low-noise amplifiers 140 and 150, and the duplexers 210 and 220 may be mounted on a single module substrate.

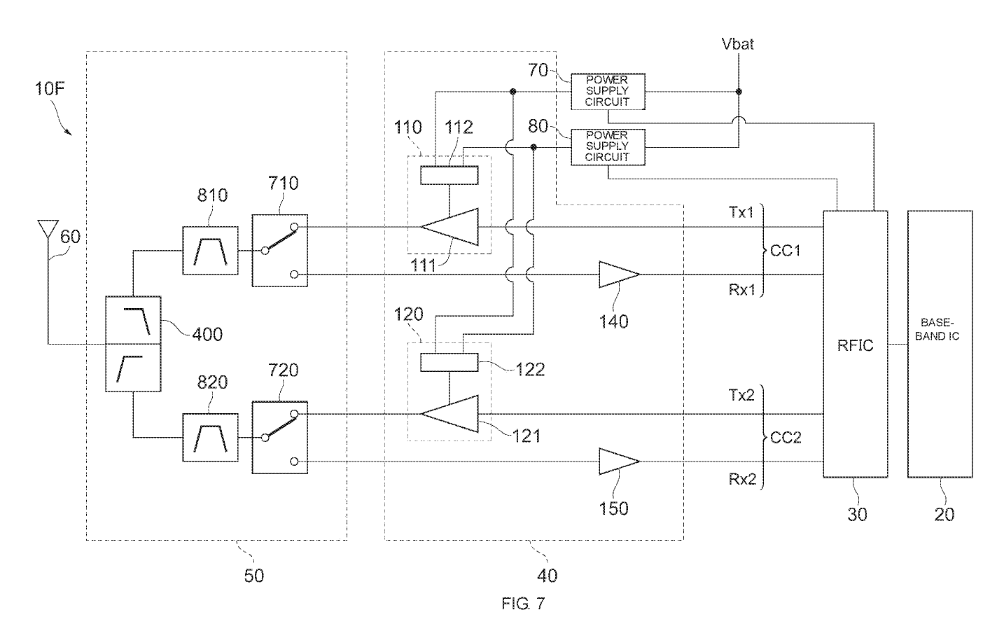

FIG. 7 illustrates a circuit configuration of a radio frequency module 10F according to a fourth embodiment of the present disclosure. The radio frequency modules 10A to 10E described above have a configuration based on a frequency division duplex (FDD) scheme in which transmit and receive signals having different frequency ranges are used and transmit and receive signals are separated in accordance with the frequency range. In contrast, the radio frequency module 10F has a configuration based on a time division duplex (TDD) scheme in which transmit and receive signals having the same frequency range are used and transmit and receive signals are separated in time.

Specifically, unlike the radio frequency module 10A, the radio frequency module 10F further includes switches 710 and 720 and includes band pass filter circuits 810 and 820 instead of the duplexers 210 and 220.

Each of the switches 710 and 720 is a one-input two-output switch. The switch 710 connects the output of the amplifier 111 (hereinafter also referred to as the power amplifier 111) to the band pass filter circuit 810 during the transmission of the transmit signal Tx1, and connects the band pass filter circuit 810 to the input of the low-noise amplifier 140 during the reception of the receive signal Rx1. In this way, the switch 710 switches between the paths of the transmit signal Tx1 and the receive signal Rx1 depending on time. The switch 720 connects the output of the amplifier 121 (hereinafter also referred to as the power amplifier 121) to the band pass filter circuit 820 during the transmission of the transmit signal Tx2, and connects the band pass filter circuit 820 to the input of the low-noise amplifier 150 during the reception of the receive signal Rx2. In this way, the switch 720 switches between the paths of the transmit signal Tx2 and the receive signal Rx2 depending on time.

The band pass filter circuit 810 has a frequency characteristic that passes the transmit signal Tx1 and the receive signal Rx1. One of the transmit signal Tx1 or the receive signal Rx1 is supplied to the band pass filter circuit 810 depending on time. The band pass filter circuit 820 has a frequency characteristic that passes the transmit signal Tx2 and the receive signal Rx2. One of the transmit signal Tx2 or the receive signal Rx2 is supplied to the band pass filter circuit 820 depending on time. Accordingly, the radio frequency module 10F, which is based on the TDD scheme, can also reduce the circuit size and cost of the power amplifier module 40.

In FIG. 7, the switches 710 and 720 and the band pass filter circuits 810 and 820 are included in the front-end module 50. The switches 710 and 720 and the band pass filter circuits 810 and 820 may be mounted on a module substrate for the front-end module 50, a module substrate for the power amplifier module 40, or any other substrate. In addition, each of the band pass filter circuits 810 and 820 may have a frequency range such that transmit and receive signals in the frequency range are transmitted therethrough, and may be constituted by a filter circuit other than a band pass filter circuit, such as a low pass filter circuit.

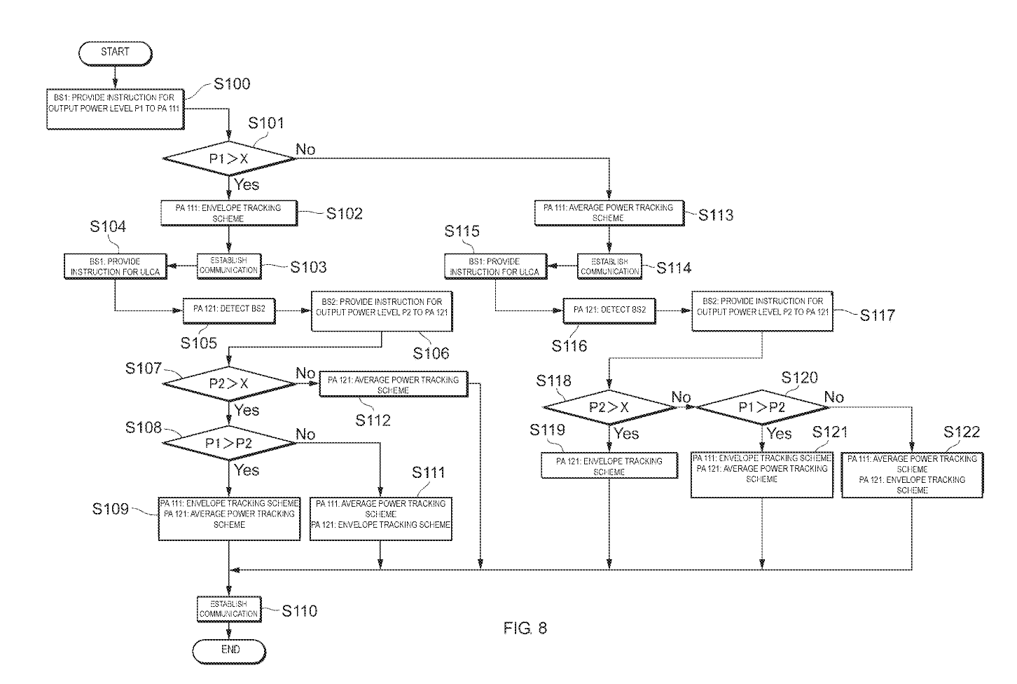

Next, an exemplary method for switching between the schemes for a power supply voltage to be supplied to each power amplifier will be described with reference to FIG. 8. FIG. 8 is a flowchart illustrating a method for determining a power supply voltage when a carrier aggregation operation is performed in the first embodiment of the present disclosure. The power supply voltage control described below may be performed by, for example, the baseband IC 20 or the RFIC 30 or may be performed by the signal processing IC 90 or the signal processing ICs 91 and 92. First, when communication between the radio frequency module 10A and a first base station (BS1) is started, the first base station provides an instruction for a level P1 of required output power to the power amplifier 111 (step S100). If the level P1 is higher than a predetermined threshold X (for example, about ten and several decibels above 1 milliwatt (dBm)) (step S101: Yes), the power amplifier 111 is supplied with a power supply voltage according to the envelope tracking scheme (step S102), and then communication is established (step S103). Then, the first base station provides an instruction for an uplink carrier aggregation operation (step S104). Then, the power amplifier 121 detects a new base station (second base station (BS2)) (step S105). The detected second base station (BS2) provides an instruction for a level P2 of required output power to the power amplifier 121 (step S106). If the level P2 is higher than the predetermined threshold X (step S107: Yes), the level P1 and the level P2 are compared. If the level P1 is higher than the level P2 (step S108: Yes), the power amplifier 111 is supplied with a power supply voltage according to the envelope tracking scheme, and the power amplifier 121 is supplied with a power supply voltage according to the average power tracking scheme (step S109). Then, communication is established (step S110). On the other hand, if the level P1 is lower than the level P2 (step S108: No), the power amplifier 111 is supplied with a power supply voltage according to the average power tracking scheme, and the power amplifier 121 is supplied with a power supply voltage according to the envelope tracking scheme (step S111). Then, communication is established (step S110). If the level P2 is lower than the predetermined threshold X (step S107: No), there is no need to compare the level P1 with the level P2, and the power amplifier 121 is supplied with a power supply voltage according to the average power tracking scheme (step S112). Then, communication is established (step S110).

On the other hand, if the level P1 is lower than the predetermined threshold X (step S101: No), the power amplifier 111 is supplied with a power supply voltage according to the average power tracking scheme (step S113). Then, communication is established (step S114).

Then, the first base station provides an instruction for an uplink carrier aggregation operation in a way similar to that in the steps described above (step S115). Then, the power amplifier 121 detects a new base station (second base station) (step S116). The detected second base station provides an instruction for the level P2 of required output power to the power amplifier 121 (step S117). If the level P2 is higher than the predetermined threshold X (step S118: Yes), there is no need to compare the level P1 with the level P2, and the power amplifier 121 is supplied with a power supply voltage according to the envelope tracking scheme (step S119). Then, communication is established (step S110). On the other hand, if the level P2 is lower than the predetermined threshold X (step S118: No), the level P1 and the level P2 are compared. If the level P1 is higher than the level P2 (step S120: Yes), the power amplifier 111 is supplied with a power supply voltage according to the envelope tracking scheme, and the power amplifier 121 is supplied with a power supply voltage according to the average power tracking scheme (step S121). Then, communication is established (step S110). On the other hand, if the level P1 is lower than the level P2 (step S120: No), the power amplifier 111 is supplied with a power supply voltage according to the average power tracking scheme, and the power amplifier 121 is supplied with a power supply voltage according to the envelope tracking scheme (step S122). Then, communication is established (step S110).

Through the steps described above, a power amplifier having a lower level of output power required by a base station is supplied with a power supply voltage according to the average power tracking scheme, and a power amplifier having a higher level of required output power is supplied with a power supply voltage according to the envelope tracking scheme. The switching between the schemes for a power supply voltage may be performed by, as described above, for example, controlling the switching operations of the switches 112 and 122 by using the baseband IC 20, the RFIC 30, or the signal processing IC 90 or the processing ICs 91 and 92.

If the levels P1 and P2 of output power of the power amplifiers 111 and 121, which are required by a base station, are substantially equal, initial setting may be performed such that, for example, one of the power amplifiers 111 and 121 is supplied with a power supply voltage according to the envelope tracking scheme and the other power amplifier is supplied with a power supply voltage according to the average power tracking scheme. In the steps described above, an example is described in which the power amplifier 121 detects the second base station different from the first base station. However, the power amplifier 121 may communicate with the first base station with which the power amplifier 111 communicates. In this case, the first base station provides an instruction for the level P2 of required output power to the power amplifier 121.

The first, third, and fourth embodiments described above exemplify two power amplifier circuits, and the second embodiment described above exemplifies three power amplifier circuits. However, four or more power amplifier circuits may be used. When the number of power amplifier circuits is denoted by M, the power supply circuit 70 supplies a power supply voltage according to the envelope tracking scheme to any one power amplifier circuit selected from among M power amplifier circuits. The power supply circuit 80 supplies a power supply voltage according to the average power tracking scheme to (M−1) power amplifier circuits, other than the selected power amplifier circuit, among the M power amplifier circuits. Here, M is an integer greater than or equal to 2. Each of the M power amplifier circuits includes a switch that switches between power supply sources so as to be supplied power from any one selected from among the power supply circuits 70 and 80. The M power amplifier circuits can also simultaneously output a plurality of RF signals having different frequency ranges by using carrier aggregation.

It is to be noted that FIGS. 1 to 7 do not illustrate a matching circuit for performing impedance matching between the preceding and subsequent circuits, for convenience of illustration. Further, the embodiments described above are intended to help easily understand the present disclosure and are not to be used to construe the present disclosure in a limiting fashion. Modifications or improvements may be made to the present disclosure without departing from the gist of the present disclosure, and their equivalents are also included in the present disclosure. That is, the embodiments may be appropriately modified in design by those skilled in the art, and such modifications also fall within the scope of the present disclosure so long as the modifications include the features of the present disclosure. Circuit elements included in the embodiments and the arrangements and so on thereof are not limited to those illustrated exemplarily but can be modified as appropriate. Circuit elements included in the embodiments can be combined as much as technically possible, and such combinations of circuit elements also fall within the scope of the present disclosure so long as the combinations of circuit elements include the features of the present disclosure.

While embodiments of the disclosure have been described above, it is to be understood that variations and modifications will be apparent to those skilled in the art without departing from the scope and spirit of the disclosure. The scope of the disclosure, therefore, is to be determined solely by the following claims.

What is claimed is:

1. A power amplifier module comprising:
a plurality of power amplifiers; and
at least one switch configured to switch connection of the plurality of power amplifiers between a power supply source that supplies a power supply voltage according to an envelope tracking scheme and a power supply source that supplies a power supply voltage according to an average power tracking scheme.

2. The power amplifier module according to claim 1, wherein
the at least one switch is configured to switch connection of a first power amplifier of the plurality of power amplifiers to the power supply source that supplies the power supply voltage according to the envelope tracking scheme and to switch connection of a second power amplifier of the plurality of amplifiers to the power supply source that supplies the power supply voltage according to the average power tracking scheme.

3. The power amplifier module according to claim 1, wherein the plurality of power amplifiers simultaneously output a plurality of radio frequency signals having different frequency ranges by using carrier aggregation.

4. The power amplifier module according to claim 2, wherein the plurality of power amplifiers simultaneously output a plurality of radio frequency signals having different frequency ranges by using carrier aggregation.

5. The power amplifier module according to claim 1, wherein a power amplifier supplied with the power supply voltage according to the envelope tracking scheme has a higher output power than a power amplifier supplied with the power supply voltage according to the average power tracking scheme.

6. The power amplifier module according to claim 2, wherein the first power amplifier supplied with the power supply voltage according to the envelope tracking scheme has a higher output power than the second power amplifier supplied with the power supply voltage according to the average power tracking scheme.

7. The power amplifier module according to claim 3, wherein a power amplifier supplied with the power supply voltage according to the envelope tracking scheme has a higher output power than a power amplifier supplied with the power supply voltage according to the average power tracking scheme.

8. The power amplifier module according to claim 4, wherein the first power amplifier supplied with the power supply voltage according to the envelope tracking scheme has a higher output power than the second power amplifier supplied with the power supply voltage according to the average power tracking scheme.

9. A radio frequency module comprising:
the power amplifier module according to claim 1; and
a plurality of filter circuits, each of the plurality of filter circuits comprising:
a plurality of duplexers, and
a pair of radio frequency switches configured to:
select, from among the plurality of duplexers, a duplexer corresponding to a frequency range of a radio frequency signal output from one of the plurality of power amplifiers, and
selectively switch between paths of the radio frequency signal such that the radio frequency signal is transmitted through the selected duplexer.

10. A radio frequency module comprising:
the power amplifier module according to claim 1;
a plurality of bandpass filters; and
a plurality of radio frequency switches, each of the radio frequency switches configured to selectively connect one of the plurality of bandpass filters to one of the plurality of power amplifiers or to a low-noise amplifier in accordance with a frequency range of a radio frequency signal passing through the switch and a time division duplex scheme.
